(19) United States
(12) Patent Application Publication
(10) Pub. No.: US 2002/0190771 A1
(43) Pub. Date: Dec. 19, 2002

(54) Flip-flop with advantageous timing

(75) Inventors: Dzung Joseph Tran, Hillsboro, OR (US); Mark Warren Acuff, Hillsboro, OR (US)

Correspondence Address: One World Trade Center, 121 S.W. Salmon Street, Portland, OR, 97204, US

(73) Assignee: Translogic Technology, Inc.

(21) Appl. No.: 10/017,303

(22) Filed: Dec. 13, 2001

Related U.S. Application Data
(60) Provisional application No. 60/299,547, filed on Jun. 19, 2001.

(51) Int. Cl. H03K 19/00

(52) U.S. Cl. 327/215

(57) ABSTRACT

A flip-flop includes an input stage to receive a data signal and an output stage to provide an output signal. A clock input is directly connected to a transmission gate of the output stage and coupled by way of a delay circuit to a transmission gate of the input stage. A first latch is coupled between the transmission gate of the input stage and the output stage.

### RELATED APPLICATION DATA

This application claims priority to provisional patent application No. 60/299,547 filed Jun. 19, 2001, entitled “Flip-Flop With Uniform Propagation Delay”, which is hereby incorporated by reference.

### TECHNICAL FIELD

This invention relates to digital circuits. More specifically, the invention relates to digital flip-flops.

### BACKGROUND

Flip-flops are digital memory devices. There are a wide variety of flip-flops, including D-type flip-flops, JK flip-flops, scan-type flip-flops, SR flip-flops, and so on. Flip-flops are often employed in high-speed circuit applications, where the clock-to-output time, setup time, and hold times of the flip-flop become important considerations. The clock-to-output (CQ) time of a flip-flop is the time between when the flip-flop receives a triggering event (for example, a low to high transition of the clock signal), to the time when the signal at the output of the flip-flop becomes valid. “Valid” refers to the signal taking on a predetermined value (in digital systems, typically values within a voltage range associated with a logical “1” or “0”). The setup time of a flip-flop is the amount of time during which the input data signal to the flip-flop must be valid and stable before the triggering event. The hold time of a flip-flop is the amount of time during which the input data signal to the flip-flop must be valid and stable after the triggering event. If either of the setup or hold times is not met, the data signal may not be properly stored by the flip-flop.

FIG. 1 is a circuit diagram of a prior art flip-flop design. The flip-flop is designed to latch the data signal upon a transition of the clock signal CK from a low to a high voltage level. While the clock signal CK is low, the deep transistor stack formed from the transistors 108, 112, 124, and 126 is “ON”, propagating the data signal from node C to node A. (The depth of the stack is a measure of the number of transistors between the voltage source and ground). The clock signal CK then transitions to high. This low-high transition first reaches the transmission gate circuit 122. An inverted form of the clock signal CK is also provided to the transmission gate via inverter 110. The transmission gate turns “ON”, propagating the data signal from node A to node B at low impedance. Upon reaching node B, the signal begins charging a loop latch formed from inverters 120 and 114. The data signal is latched when the loop latch is charged to the data signal level. The latched signal and its bar (logical complement) are provided at the outputs Q and QB of the flip-flop by inverters 116 and 118, respectively. Thus, for a short time after the clock signal transitions from low to high, node C is coupled to node B through a low-impedance signal path. During this time, the loop latch is charged (or discharged) to the data signal level by current supplied from the deep transistor stack.

After a delay time provided by the inverters 102-106, the high clock signal CK reaches the transistors 108 and 126, and the deep transistor stack turns “OFF”. Current is no longer provided to charge the loop latch. Thus, the time available to latch the data signal is approximately equal to the delay time provided by the transistors 102-106.

The time that it takes for the loop latch to charge is proportional to the amount of current provided from the transistor stack. Due to its series configuration, a deeper stack comprises greater impedance between source and common, providing less current than a shallower stack, consequently increasing the CQ time of the flip-flop. Thus, to meet the rigid timing requirements for charging the loop latch within the delay time, the transistors 108, 112, 124, and 126 need to provide a large amount of current in a short amount of time. Using larger, higher-current transistors can meet this need, but result in larger circuits and increased power consumption. Alternatively, the delay provided by the transistors 102-106 may be increased to provide a longer charging interval. However, this increases the flip-flop's hold time.

### SUMMARY

In one aspect, a flip-flop includes an input stage to receive a data signal and an output stage to provide an output signal. A clock input is directly connected to a transmission gate of the output stage and coupled by way of a delay circuit to a transmission gate of the input stage. A first latch is coupled between the transmission gate of the input stage and the output stage.

In another aspect, a flip-flop includes an input stage and an output stage, the input stage configured to receive a delayed version of a clock signal applied to the output stage, such that a latch of the input stage charges a latch of the output stage during a time when a transmission gate of the input stage is OFF and a transmission gate of the output stage is ON, and such that the latch of the input stage and the latch of the output stage are ON during a time while the clock signal is delayed to the input stage.

In yet another aspect, a flip-flop includes an input stage to receive a data signal and an output stage to provide an output signal. A clock input is directly connected to a first pair of cross-coupled transmission gates of the output stage and coupled by way of a delay circuit to a second pair of cross-coupled transmission gates of the input stage.

In yet another aspect, a flip-flop includes an input stage configured to propagate a data signal to an output stage during a low period of a clock signal and to block the data signal from propagating to the output stage during a high period of a clock signal. The output stage is configured to propagate the data signal to an output of the flip-flop during a high period of the clock signal and to block the data signal from propagating to the output during a low period of a clock signal. A delay circuit delays the clock signal to the input stage, and a first latch charges a second latch to the data signal level during a time when the input stage is blocking propagation of the data signal to the output stage, and the output stage is propagating the data signal to the output.

In yet another aspect, a flip-flop includes an input stage to receive a data signal and an output stage to provide an output signal, the input stage comprising a single transmission gate. A clock input is directly connected to a pair of cross-coupled transmission gates of the output stage and coupled by way of a delay circuit to the single transmission gate of the input stage. A first loop latch is coupled between the single transmission gate of the input stage and the output stage.

In yet another aspect, a flip-flop includes an input stage to receive a data signal and an output stage to provide an output signal, the output stage comprising a single transmission gate. A clock input is directly connected to the single transmission gate of the output stage and coupled by way of a delay circuit to a pair of cross-coupled transmission gates of the input stage. The pair of cross-coupled transmission gates of the input stage are coupled by way of a single inverter to the single transmission gate of the output stage.

### DRAWINGS

FIG. 1 is a circuit diagram of a prior art flip-flop.

FIG. 2 is a circuit diagram of an embodiment of a low CQ flip-flop.

FIG. 3 is a circuit diagram of another embodiment of a low CQ flip-flop.

### DESCRIPTION

In the following figures and description, like numbers refer to like elements. References to “one embodiment” or “an embodiment” do not necessarily refer to the same embodiment, although they may. Although various embodiments are illustrated in terms of particular N and P type transistors, those skilled in the art will appreciate that circuits employing other transistor technologies, and operationally analogous configurations of N and P type transistors, may also operate in accordance with the present invention.

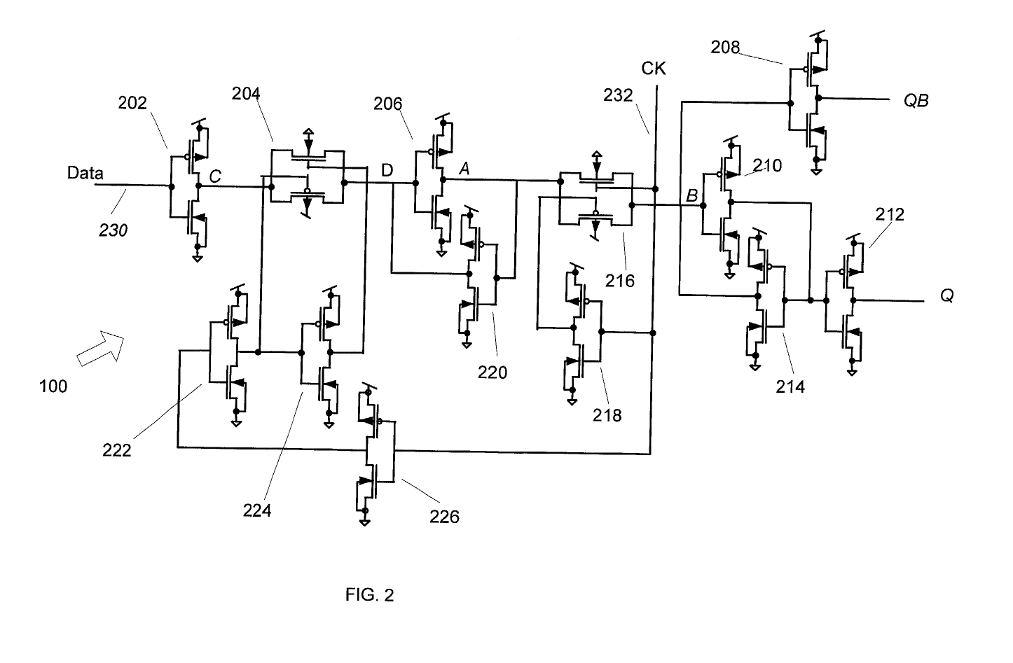

With reference to FIG. 2, a flip-flop embodiment 100 comprises an output stage comprising a transmission gate 216 and inverters 208, 210, 212, 214, and 218. The inverters 210 and 214 form an output stage loop latch to latch a signal at node B. Output signal Q and QB are provided by way of inverters 212 and 208, respectively. An input stage of the flip-flop 100 comprises a transmission gate 204 and inverters 202, 206, and 220. The input stage receives a data signal on data signal input 230. The inverters 206 and 220 form an input stage loop latch to latch a signal at node D. The inverter 202 acts as a buffer for the data signal. The flip-flop further comprises a delay circuit, comprising transistors 222, 224, and 226.

The delay circuit may comprise a plurality of combinational logic gates in series, where a combinational logic gate comprises one of an inverter, OR gate, AND gate, NOR gate, NAND gate, and XOR gate. As used herein, the term “combinational logic gate” also includes transmission gates and other signal gating devices which are configured to be always ON. The amount of delay provided by the delay circuit may vary, but will always cause the clock signal to trigger the input stage at a later time than the clock signal triggers the output stage.

A clock signal CK is provided on clock input 232. During a time when the clock signal CK is low, the transmission gate 204 is “ON”, and the input stage loop latch charges to the data signal level. A low-high transition of the clock signal CK first reaches the transmission gate 216. An inverted form of the clock signal CK is also provided to the transmission gate via inverter 218. The transmission gate 216 turns “ON”, propagating the data signal latched by the input stage loop latch to node B. Upon reaching node B, the output stage loop latch begins to charge to the data signal level.

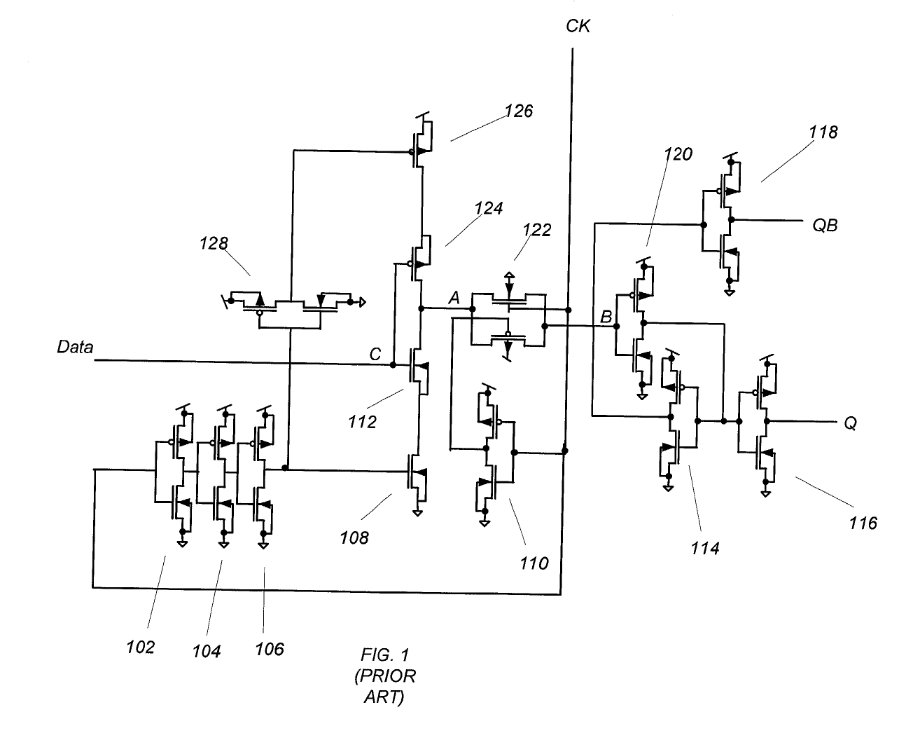

After the delay provided by the inverters 222-226, the high clock signal CK reaches the transmission gate 204, and the gate 204 turns “OFF”. The transmission gate 216 remains “ON” until the clock signal CK transitions back to low. However, unlike the prior art flip-flop of FIG. 1, current is still provided from the input stage loop latch to charge the output stage loop latch to the data signal level, until the clock signal CK transitions back to low. The flip-flop 100 thus provides a longer latching interval, even when the delay provided by the inverters 222-226 is small. The time available to charge the output loop latch is approximately equal to the entire time the clock signal is high.

In the prior art design of FIG. 1, the delay time applied to the clock signal must be large enough to enable the deep transistor stack to charge the output stage latch while the stack is turned “ON”. This increases the prior-art flip-flop's hold time. The prior art design of FIG. 1 also has a higher CQ time, because the deep transistor stack is unable to provide the large charging currents required to quickly charge the output stage latch. By contrast, the flip-flop 100 of FIG. 2 employs a “shallow” transistor stack (inverter 206) for charging the output stage loop latch. Shallow stacks, comprising fewer transistors in series, may, for a given component size, produce higher charging currents than deeper stacks, due to the lower series impedance of shallow stacks between source and common. Thus, the flip-flop 100 has an improved CQ time over the prior art flip-flop of FIG. 1.

Regarding the hold time, in the flip-flop 100 the delay applied to the clock signal CK may be fairly short, because the input stage latch can charge the output stage latch during the entire interval while the clock is high, not just during the delay interval. Thus, the flip-flop 100 can have a smaller clock delay and thus an improved hold time over the prior-art flip flop.

Conventional circuit design techniques teach that inserting additional elements in the data signal path will increase propagation delays in the circuit. This approach may be seen to some extent in the flip-flop design of FIG. 1, which attempts to minimize the number of components between the data input (node C) and the output Q. Furthermore, conventional flip-flop designs have taken the opposite approach of the present invention, e.g. delaying application of the clock signal to the output stage with respect to the time of application to the input stage. A drawback of this approach is that increasing the clock delay to the output stage increases the CQ time. Thus, the conventional thinking in flip-flop design has been that applying delays to the clock signal will adversely impact the CQ time. Also, the conventional approach to adding delay between the data signal path and the output increases the setup time of flip-flops.

However, as the flip-flop 100 demonstrates, it is possible to provide an input stage latch in series with the data signal, combined with a delay of the clock signal CK to the input stage, to actually decrease the CQ time. Note that in FIG. 2 the clock signal CK is directly connected to the output stage, without intervening inverters or other components that operate to increase the CQ time. The CQ time of the flip-flop 100 is reduced to the propagation delay of the transmission gate 216 and the propagation delay inherent in the output stage inverters 208-214. The clock signal delay to the input stage actually benefits the CQ time by removing nearly all delay between the clock signal CK and the output stage. The setup time of the flip-flop 100 is actually decreased by approximately the delay time, despite the presence of additional components between the data signal path and the output.

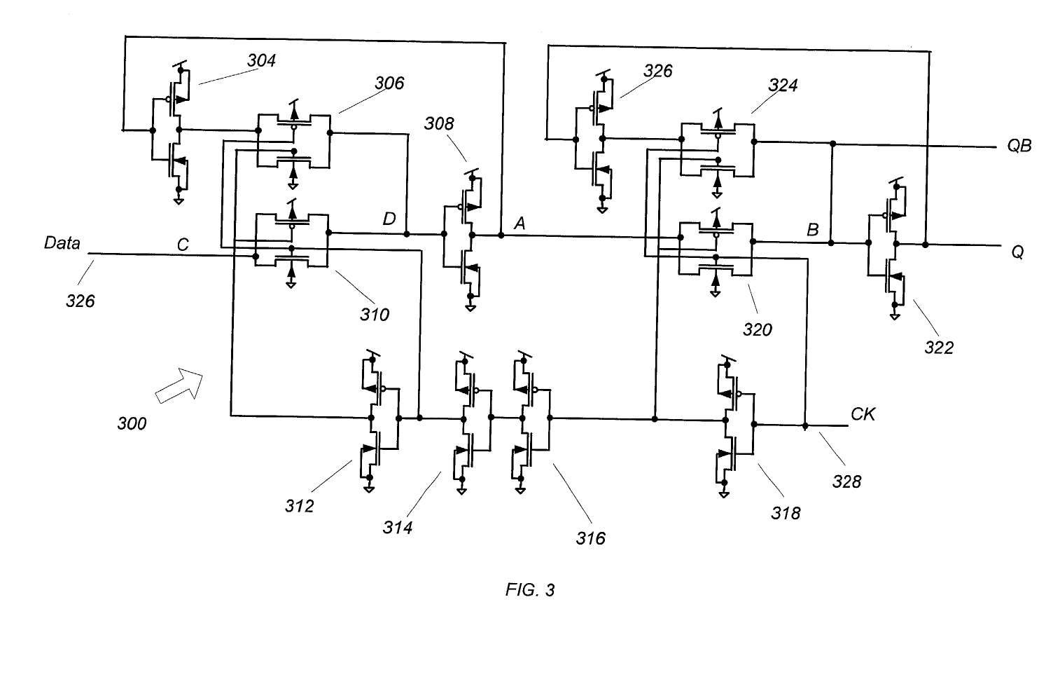

With reference to FIG. 3, another embodiment 300 of a flip-flop includes cross-coupled transmission gates and inverter loops in the input and output stages. An output stage latch comprises cross-coupled transmission gates 320, 324 and inverters 322, 326. A clock signal CK is provided on clock input 328. An inverter 318 provides an inverted form of the clock signal CK to the transmission gates 320, 324. An input stage latch comprises cross-coupled transmission gates 306, 310 and inverters 304, 308. A data signal is provided on data signal input 326. The flip-flop further comprises a delay circuit formed from the inverters 312-316. Note that neither the input stage nor the output stage of the flip-flop 300 comprises a loop latch; rather, each stage, including the cross-coupled transmission gates, operates as a latch.

The flip-flop 300 operates in a manner similar to the flip-flop 100 of FIG. 2, providing a low CQ time without compromising hold time, transistor sizes, or power consumption. The setup time of the flip-flop 300 may be decreased from the setup time of the flip-flop 100, because the inverter 202 for buffering the input data signal may be omitted.

Various hybrid embodiments of the flip-flops of FIGS. 2 and 3 may be devised. For example, one embodiment of a flip-flop comprises the input stage of the flip-flop 100 of FIG. 2, the output stage of the flip-flop 300 of FIG. 3, and a delay circuit between the clock signal CK and the input stage. Another embodiment comprises the input stage of the flip-flop 300 of FIG. 3, the output stage of the flip-flop 100 of FIG. 2, and a delay circuit between the clock signal CK and the input stage.

Those skilled in the art will recognize that the principles of the present invention may be applied to form various other types of flip-flops, including scan type flip-flops, JK type flip-flops, and set-reset (SR) type flip-flops.

In view of the many possible embodiments to which the principles of the present invention may be applied, it should be recognized that the detailed embodiments are illustrative only and should not be taken as limiting in scope. Rather, the present invention encompasses all such embodiments as may come within the scope and spirit of the following claims and equivalents thereto.

What is claimed is:

1. A flip-flop, comprising:
an input stage to receive a data signal and an output stage to provide an output signal;
a clock input directly connected to a transmission gate of the output stage and coupled by way of a delay circuit to a transmission gate of the input stage; and
a first latch coupled between the transmission gate of the input stage and the output stage.

2. The flip-flop of claim 1, wherein the first latch comprises a loop latch.

3. The flip-flop of claim 2 further comprising:
the first latch configured to charge a second latch of the output stage during a time while a clock signal is delayed to the input stage.

4. The flip-flop of claim 1, the delay circuit further comprising:
a plurality of combinational logic gates in series.

5. A flip-flop, comprising:
an input stage and an output stage, the input stage configured to receive a delayed version of a clock signal applied to the output stage, such that a latch of the input stage charges a latch of the output stage during a time when a transmission gate of the input stage is OFF and a transmission gate of the output stage is ON, and such that the latch of the input stage and the latch of the output stage are ON during a time while the clock signal is delayed to the input stage.

6. The flip-flop of claim 5 configured such that application of the clock signal to the output stage causes a data signal to propagate through the input stage to a flip-flop output for a period of time ending when a delayed clock signal is received by the input stage.

7. A flip-flop, comprising:
an input stage to receive a data signal and an output stage to provide an output signal; and
a clock input directly connected to a first pair of cross-coupled transmission gates of the output stage and coupled by way of a delay circuit to a second pair of cross-coupled transmission gates of the input stage.

8. The flip-flop of claim 7 configured such that application of a clock signal on the clock input to the output stage causes a data signal to propagate through the input stage to a flip-flop output providing the output signal for a period of time ending when the clock signal propagates through the delay circuit and reaches the input stage.

9. The flip-flop of claim 9, the delay circuit further comprising:
a plurality of combinational logic gates in series.

10. A flip-flop comprising:
an input stage configured to propagate a data signal to an output stage during a low period of a clock signal and to block the data signal from propagating to the output stage during a high period of a clock signal;
the output stage configured to propagate the data signal to an output of the flip-flop during a high period of the clock signal and to block the data signal from propagating to the output during a low period of a clock signal;
a delay circuit to delay the clock signal to the input stage; and
a first latch to charge a second latch to the data signal level during a time when the input stage is blocking propagation of the data signal to the output stage, and the output stage is propagating the data signal to the output.

11. A method comprising:
applying a clock signal to an output stage of a flip-flop;
delaying application of the clock signal to an input stage of the flip-flop;
charging a latch of the input stage with a data signal during a time when the input stage is ON and the output stage is OFF; and
the latch of the input stage charging a latch of the output stage during a time when the input stage is OFF and the output stage is ON.

12. The method of claim 11 wherein applying the clock signal to the output stage of a flip-flop causes the data signal to propagate through both the input stage and output stage to an output of the flip-flop until a time when the clock signal is applied to the input stage.

13. A flip-flop comprising:
an input stage to receive a data signal and an output stage to provide an output signal, the input stage comprising a single transmission gate;
a clock input directly connected to a pair of cross-coupled transmission gates of the output stage and coupled by way of a delay circuit to the single transmission gate of the input stage; and
a first loop latch coupled between the single transmission gate of the input stage and the output stage.

14. A flip-flop comprising:
an input stage to receive a data signal and an output stage to provide an output signal, the output stage comprising a single transmission gate;
a clock input directly connected to the single transmission gate of the output stage and coupled by way of a delay circuit to a pair of cross-coupled transmission gates of the input stage; and
the pair of cross-coupled transmission gates of the input stage coupled by way of a single inverter to the single transmission gate of the output stage.
